(19) United States
(12) Patent Application Publication
(10) Pub. No.: US 2025/0194041 A1
(43) Pub. Date: Jun. 12, 2025

(54) ADJUSTABLE WIND GUIDE HOOD STRUCTURE

(71) Applicant: PORTWELL INC., NEW TAIPEI CITY (TW)

(72) Inventor: Ya-Tzu SHIH, NEW TAIPEI CITY (TW)

(21) Appl. No.: 18/639,508

(22) Filed: Apr. 18, 2024

(30) Foreign Application Priority Data
Dec. 8, 2023 (TW) 112213469

(51) Int. Cl. H05K 7/20

(52) U.S. Cl. CPC H05K 7/20145; H05K 7/20718

(57) ABSTRACT

An adjustable wind guide hood structure includes: a wind guide hood device mounted on a fan device and having a hood housing with an exit plate part disposed at the front of the hood housing and a hood lid disposed at the top of the hood housing and having snap bumps on the inner side of the exit plate; a wind guide adjustment device including an adjustment part fixed to the hood lid and pivoted by a pivot and a wind deflector connected to the pivot, a side edge of the rear of the wind deflector is provided with a side deflection plate, and the side deflection plate having snap holes. When the wind deflector rotates downwardly from a horizontal position, the snap hole and the snap bump are snapped and engaged with each other, so as to provide different angular states of the wind deflector for use.

### FIELD OF THE INVENTION

The present disclosure relates to a wind guide hood structure, and more particularly to an adjustable wind guide hood structure that aims at the angular adjustment of the direction of airflow of a cooling device and provides a convenient assembly.

### BACKGROUND OF THE INVENTION

### 1. Description of the Related Art

As the computer and information industry advances rapidly and the scope of their applications expands significantly, the performance of computer server systems is enhanced, resulting in higher temperature or more heat from the operation of the computer server systems. In order to ensure stable operations, it is a common technical means to provide cooling devices for the computer server systems to dissipate the heat generated by the electronic components. In addition, a wind guide hood and a fan are also installed within the computer device to enhance the heat dissipation of cooling devices. However, most of the related-art wind guide hoods are fixed structures, which is unable to adjust the airflow direction and often results in poor cooling efficiency when different sized cooling devices are used to assist the heat dissipation. Obviously, such design is undesirable. Furthermore, the wind guide hood often touches the parts of the cooling devices during installation, resulting in the interference issue in the assembly, and the disassembling and assembling of the wind guide hood are quite inconvenient and troublesome during the replacement of the wind guide hood. The related-art wind guide hoods definitely need further improvements. Therefore, how to overcome the drawbacks of the related-art wind guide hood is an important subject for the related industry and manufacturers.

In view of the drawbacks and undesirable design of the related-art wind guide hood structure, the inventor of the present disclosure has conducted research and experiment for a feasible solution and provided an improved structure of an adjustable wind guide hood with the features of good wind direction adjustment, high heat dissipation efficiency and easy assembly to serve the public and promote the development of this industry. The present disclosure has been created after a long time of conceptualization.

### 2. Summary of the Invention

Therefore, it is a primary objective of the present disclosure to provide a technical means capable of assisting the cooling devices to dissipate the heat with good angular adjustment of the airflow direction and good cooperation with different sized cooling devices and to provide a better cooling effect.

Another objective of the present disclosure is to provide a technical means that simultaneously provides easy and convenient assembly of the wind guide hood and eliminate the interference issue of the wind guide hood occurred during installation.

To achieve the aforementioned and other objectives, the present disclosure provides a wind guide hood device mounted on a fan device, the wind guide hood device includes: a hood housing, wherein the hood housing at least includes an exit plate part and a hood lid, the exit plate part is disposed at the front of the hood housing, the top of the inner side of the exit plate part is provided with a plurality of snap bumps, and the hood lid is disposed on the top of the hood housing; a wind guide adjustment device, wherein the wind guide adjustment device includes an adjustment part and a wind deflector, the adjustment part is fixed to the hood lid, the adjustment part is pivoted by a pivot, the wind deflector is connected to the pivot, a side edge of the rear of the wind deflector is provided with a side deflection plate, the side deflection plate is provided with a plurality of snap holes. When the wind deflector rotates downwardly from a horizontal position, the snap hole and the snap bump are snapped and engaged with each other, so as to provide a plurality of different angular positioning states of the wind deflector.

In this embodiment, the hood housing includes a fan cover, a hollow portion defined under the fan cover, and a plate connection part installed at the front of the fan cover.

In this embodiment, the front of the plate connection part is provided with a tapered plate part, and the front of the tapered plate part is connected to the exit plate part.

In this embodiment, the hood lid is protruded out of the tapered plate part and entered into the exit plate part slightly.

In this embodiment, the plate connection part comprises a wind guide hood base plate at a position ahead that reaches the exit plate part, the bottom of the front edge of the wind guide hood base plate is provided with a groove, and the groove is mounted with a protection part which is made of a silicone material.

In this embodiment, the front edge of the hood lid is provided with a pivot notch, and the pivot notch is configured to be corresponsive to the pivot.

In this embodiment, the top of two inner sides of the exit plate part is at least provided with a first elastic bracket and a second elastic bracket which are used to form the plurality of snap bumps.

In this embodiment, the first elastic bracket and the second elastic bracket are provided with a first side slot and a second side slot on three surrounding sides thereof respectively, an edge of a separating end of the first elastic bracket is provided with a first snap bump, and an edge of a separating end of the second elastic bracket is provided with a second snap bump

In this embodiment, the wind deflector comprises a thinner front deflection plate installed to the front thereof, mounted with a wind deflector protection part which is made of a silicone material.

In this embodiment, the hood housing is made of a plastic material.

In this embodiment, the fan cover is mounted on the fan device.

In this embodiment, the wind deflector at least includes three positioning states, a horizontal position, a 30-degree downward rotational position and a 45-degree downward rotational position, provided for the selection of use.

In this embodiment, the wind guide hood device is separately and invertedly installed on two sides of a cooling device, the two wind deflectors are configured to be opposite to the cooling device.

The technical characteristics and effects of the present disclosure will become clearer in light of the following detailed description of an illustrative embodiment of this invention described in connection with the drawings.

### BRIEF DESCRIPTION OF THE DRAWINGS

FIG. 1 is a perspective view of the present disclosure;

FIG. 2 is an exploded view of the present disclosure;

FIG. 3 is a cross-sectional view of the present disclosure;

FIG. 4 is a first schematic view showing an adjustment state of the present disclosure;

FIG. 5 is a second schematic view showing an adjustment state of the present disclosure;

FIG. 6 is a third schematic view showing an adjustment state of the present disclosure; and

FIG. 7 is a cross-sectional view showing an application of the present disclosure.

### DESCRIPTION OF THE PREFERRED EMBODIMENTS

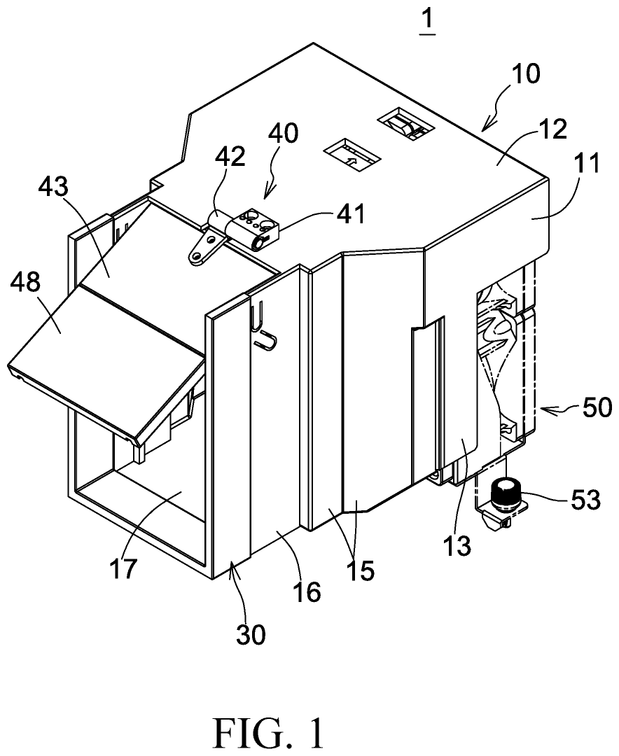

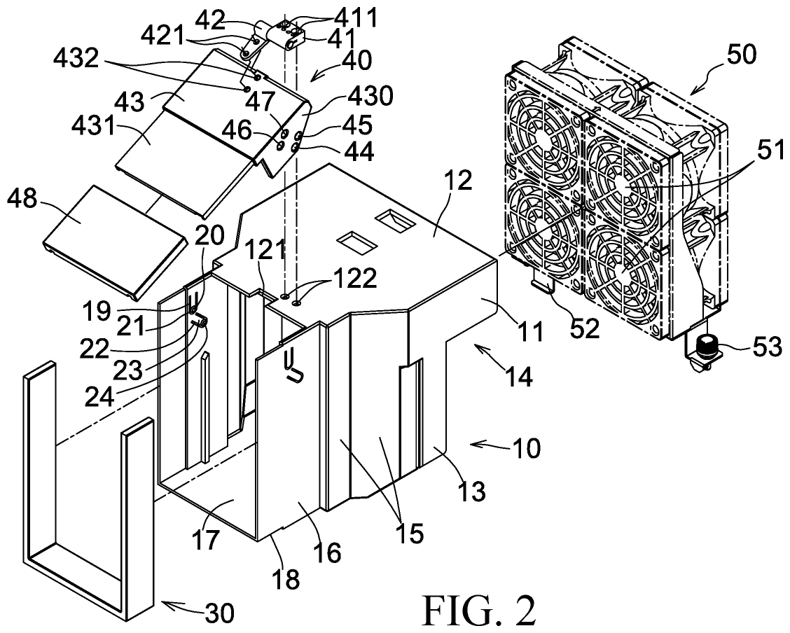

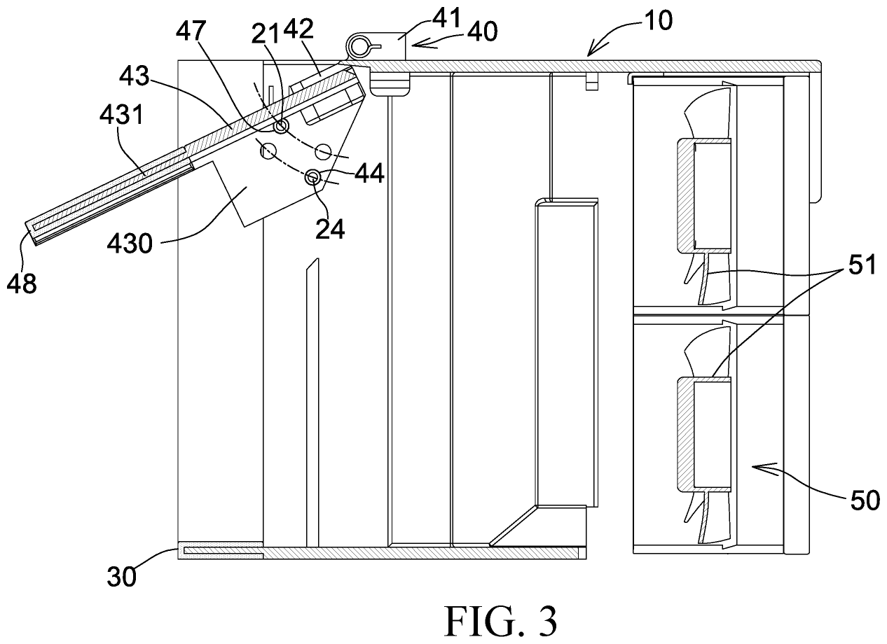

With reference to FIGS. 1, 2 and 3 for an adjustable wind guide hood structure in accordance with an embodiment of the present disclosure, the present disclosure discloses a wind guide hood device 1 including a hood housing 10, a protection part 30 and a wind guide adjustment device 40. The hood housing 10 is a shell assembly which includes a fan cover 11 having a hollow portion 14 defined at the bottom of the fan cover 11, a plate connection part 13 disposed at the front of the fan cover 11 (in the direction indicated in FIG. 1, and the same applies hereinafter), a tapered plate part 15 disposed at the front of the plate connection part 13, and an exit plate part 16 disposed at the front of the tapered plate part 15. The fan cover 11 has a hood lid 12 disposed at the top of the fan cover 11 and extended forwardly to the tapered plate part 15. In this embodiment, the hood lid 12 is protruded out of the tapered plate part 15 and entered into the exit plate part 16 slightly, but this disclosure is not limited to such arrangement. The front edge of the hood lid 12 is provided with a pivot notch 121, and an appropriate position on a side of the pivot notch 121 is provided with two fixing holes 122. In addition, the plate connection part 13 has a wind guide hood base plate 17 extending forward to the exit plate part 16, and the bottom of the front edge of the wind guide hood base plate 17 of the exit plate part 16 (hood housing 10) is provided with a groove 18.

The tops of two inner sides of the exit plate part 16 are provided with a first elastic bracket 20 and a second elastic bracket 23 respectively, the first elastic bracket 20 is installed longitudinally, the first elastic bracket 20 is formed by its three surrounding sides with a first side slot 19, a separating end at an edge of the first elastic bracket 20 is provided with a first snap bump 21. The second elastic bracket 23 is disposed below the first elastic bracket 20 and arranged obliquely, the second elastic bracket 23 is formed by its three surrounding sides with a second side slot 22, and a separating end at an edge of the second elastic bracket 23 is provided with a second snap bump 24.

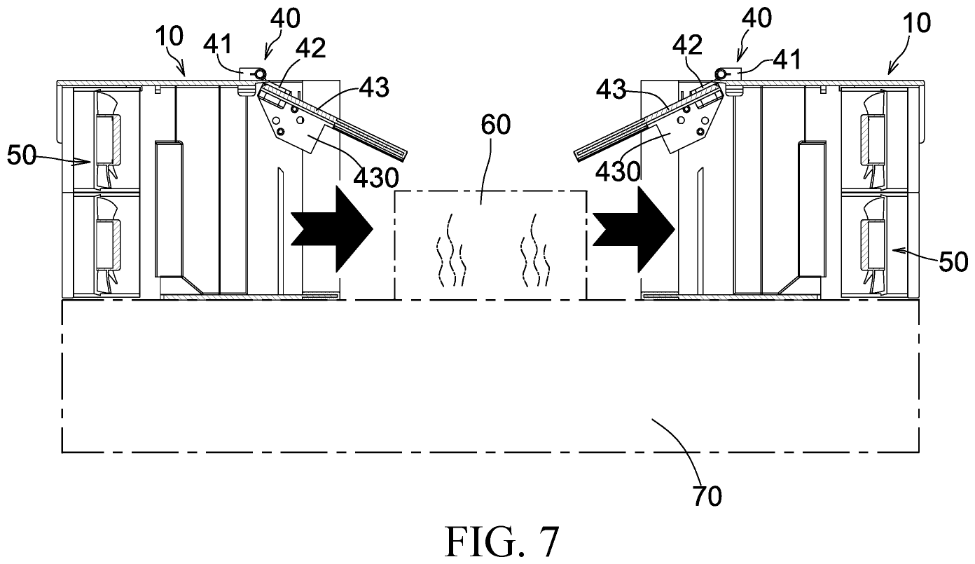

The protection part 30 is made of a silicone material and formed as a U-shaped assembly. The protection part 30 is disposed at the groove 18 of the wind guide hood base plate 17 and provided for covering the periphery of the front edge of the exit plate part 16 (hood housing 10). In an embodiment, the hood housing 10 made of a plastic material in conjunction with the protection part 30 made of a silicone material can prevent the interference issue caused by touching other components (such as the cooling device 60 as shown in FIG. 7) during the installation of the hood housing 10.

The wind guide adjustment device 40 is installed on the hood lid 12 and includes an adjustment part 41 and a wind deflector 43, the adjustment part 41 has two positioning holes 411, the positioning holes 411 are fixed to the fixing holes 122 of the hood lid 12 by screws, such that the adjustment part 41 is combined onto the hood lid 12; the adjustment part 41 is pivotally connected by a pivot 42, and the front end of the pivot 42 is provided with two connection positioning holes 421. The rear of the wind deflector 43 is provided with two fixing holes 432, the fixing holes 432 are fixed to the connection positioning holes 421 of the pivot 42 by screws, such that the wind deflector 43 is combined onto the pivot 42 and linked with the pivot 42, and the pivot 42 is aligned precisely with the pivot notch 121, such that the pivot 42 can be adjusted to different downwardly rotational angles. Two sides of the rear of the wind deflector 43 are separately provided with a side deflection plate 430, the front of the wind deflector 43 is provided with a thinner front deflection plate 431, wherein the rear of the side deflection plate 430 is provided with a lower group of snap holes including a first snap hole 44 and a second snap hole 45, and the first snap hole 44 is disposed at a position lower than the second snap hole 45; and the front of the side deflection plate 430 is provided with a higher group of snap holes including a third snap hole 46 and a fourth snap hole 47, and the third snap hole 46 is disposed at a position lower than the fourth snap hole 47.

The wind guide adjustment device 40 further includes a wind deflector protection part 48 which is made of a silicone material, the wind deflector protection part 48 is mounted onto the front deflection plate 431 and provided for covering the front deflection plate 431 (the periphery of the front of the wind deflector 43). In an embodiment, the wind deflector 43 made of a plastic material in conjunction with the wind deflector protection part 48 made of a silicone material can prevent the interference issue caused by touching other components (such as the cooling device 60 as shown in FIG. 7) during the installation of the wind deflector 43 (hood housing 10).

In the assembly above, a fan device 50 is installed at the fan cover 11 of the hood housing 10. In other words, the hood housing 10 is mounted onto the fan device 50, and the fan device 50 is disposed under the fan cover 11. The fan device 50 is a fan module composed of a plurality of fans 51, two sides of the fan device 50 are provided with a screw fastening part 53 for screwing and fixing an equipment 70 (as shown in FIG. 7), and the equipment 70 can be an internal or external housing of a system equipment. The bottom of the fan device 50 is provided with a positioning part 52 for pre-fixing the fan device 50 on the equipment 70 before assembling, so as to facilitate the assembling and positioning operations of the fan device 50.

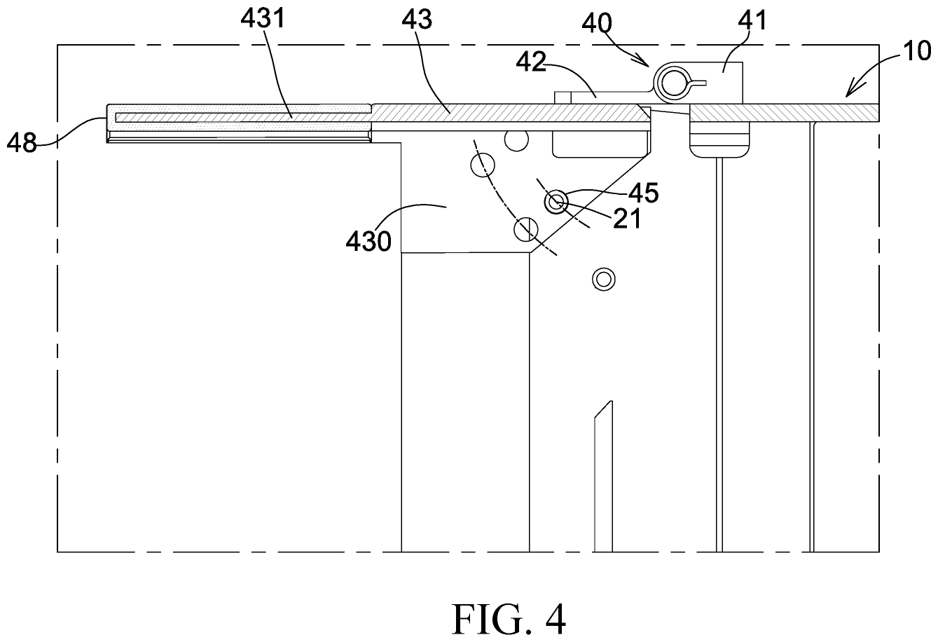

With reference to FIG. 4 for the first embodiment of an adjustable wind guide hood structure of the present disclosure, when the wind deflector 43 is located at a horizontal position, the first snap bump 21 is snapped into the second snap hole 45 to define positioning, and even if the wind deflector 43 is temporarily maintained at the horizontal position, the wind deflector 43 will remain unmoved.

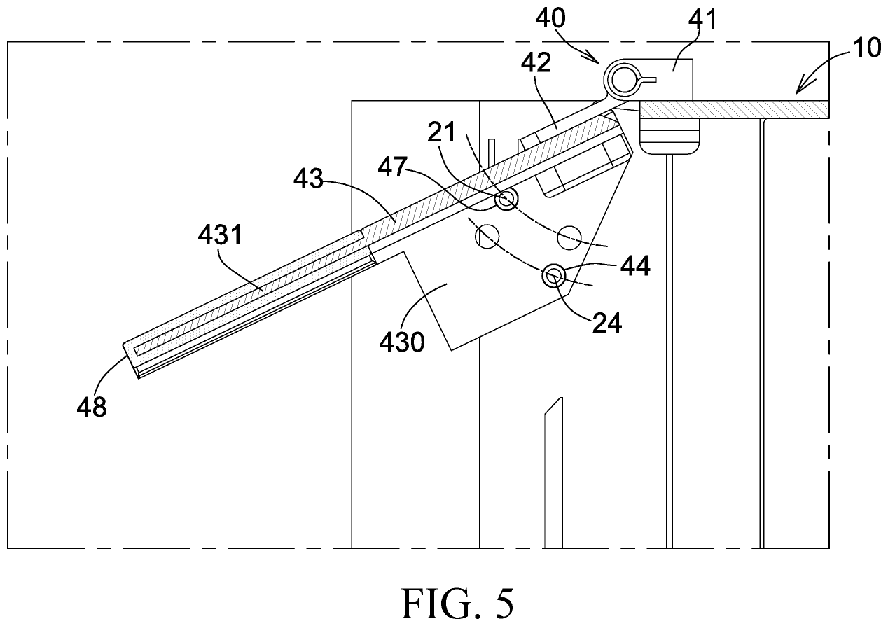

With reference to FIG. 5 for the second embodiment of an adjustable wind guide hood structure of the present disclosure, when the wind deflector 43 is adjusted and downwardly rotated to an approximately 30-degree position, the second snap bump 24 is snapped into the first snap hole 44 and the first snap bump 21 is snapped into the fourth snap hole 47 to define positioning, even if the wind deflector 43 is temporarily maintained at the approximately 30-degree position, the wind deflector 43 will remain unmoved.

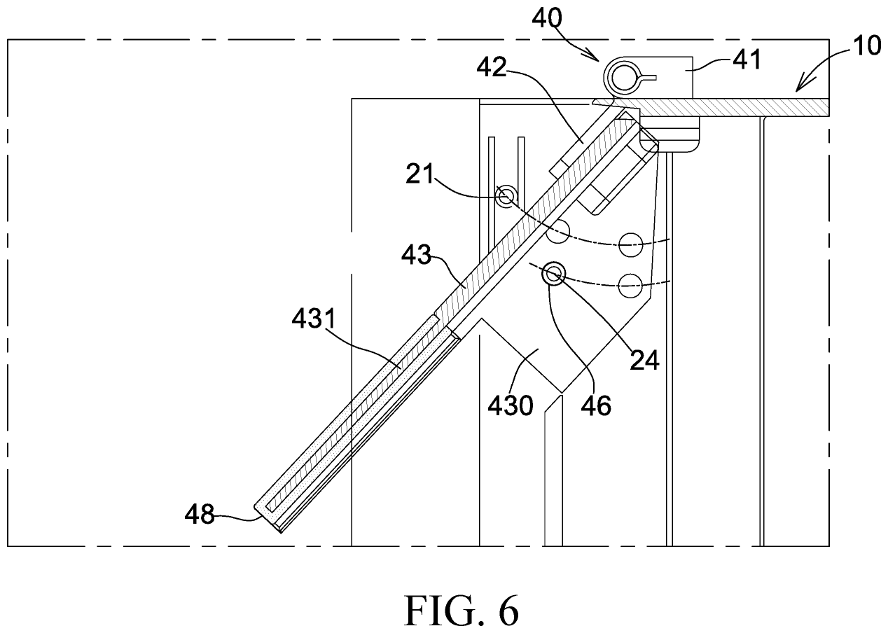

With reference to FIG. 6 for the third embodiment of an adjustable wind guide hood structure of the present disclosure, when the wind deflector 43 is adjusted and downwardly rotated to an approximately 45-degree position, the second snap bump 24 is snapped into the third snap hole 46 to define positioning, and even if the wind deflector 43 is temporarily maintained at the approximately 45-degree position, the wind deflector 43 will remain unmoved.

In the assembly above, the wind deflector 43 has three (or other) different adjusted positions allows the exit plate part 16 in conjunction with the wind deflector 43 to define three different airflow defection angles, so that when airflow from the fan device 50 passes through the wind deflector 43 in different directions to adjust a cooling device 60 of a different size or height (as shown in FIG. 7), so as to avoid an airflow loss, and actively improve the cooling efficiency of the cooling device 60.

With reference to FIG. 7 for an application of the adjustable wind guide hood in accordance with an embodiment of the present disclosure, the cooling device 60 (such as a heat dissipating fin module) mounted on the equipment 70, two sides of the cooling device 60 are separately and invertedly installed with the hood housing 10 (or wind guide hood device 1), the wind deflector 43 is downwardly adjusted to the approximately 30-degree position, and the two wind deflectors 43 are configured to be opposite to the cooling device 60 in the direction indicated in the figure. One of the hood housings 10 (or the wind guide hood device 1) blows air, and the other hood housing 10 (or the wind guide hood device 1) sucks air, so as to further improve the cooling efficiency of the cooling device 60 (such as the heat dissipating fin module).

The adjustable wind guide hood structure in accordance with the present disclosure can assist the heat dissipation of the cooling device and adjust the airflow angle, so that it can be used in conjunction with the cooling devices of different sizes to achieve a better cooling effect; and at the same time, the present disclosure can also provide an easy and convenient assembly of the wind guide hood and eliminate the interference issue caused by touching other components during the installation of the wind guide hood.

While the technical characteristics and functions of the present disclosure have been described by way of examples and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures. It is noteworthy that the embodiments and figures disclosed herein are to be considered illustrative rather than restrictive.

What is claimed is:

1. An adjustable wind guide hood structure, comprising a wind guide hood device, mounted on a fan device, the wind guide hood device comprising:
a hood housing, comprising an exit plate part and a hood lid, the exit plate part being disposed at the front of the hood housing, the top of the inner side of the exit plate part being provided with a plurality of snap bumps, and the hood lid being disposed at the top of the hood housing;
a wind guide adjustment device, comprising an adjustment part and a wind deflector, the adjustment part being fixed to the hood lid, the adjustment part being pivoted with a pivot, the wind deflector being coupled to the pivot, a side edge of the rear of the wind deflector being provided with a side deflection plate, and the side deflection plate is provided a plurality of snap holes;
wherein, when the wind deflector rotates downwardly from a horizontal position, the snap hole and the snap bump are snapped and engaged with each other, so as to provide a plurality of different angular positioning states of the wind deflector.

2. The adjustable wind guide hood according to claim 1, wherein the hood housing comprises a fan cover, a hollow portion defined under the fan cover, and a plate connection part installed at the front of the fan cover.

3. The adjustable wind guide hood according to claim 2, wherein the front of the plate connection part is provided with a tapered plate part, and the front of the tapered plate part is coupled to the exit plate part.

4. The adjustable wind guide hood according to claim 3, wherein the hood lid is protruded out from the tapered plate part and entered into the exit plate part slightly.

5. The adjustable wind guide hood according to claim 4, wherein the plate connection part comprises a wind guide hood base plate at a position ahead that reaches the exit plate part, the bottom of the front edge of the wind guide hood base plate is provided with a groove, and the groove is mounted with a protection part which is made of a silicone material.

6. The adjustable wind guide hood according to claim 1, wherein the front edge of the hood lid is provided with a pivot notch, and the pivot notch is configured to be corresponsive to the pivot.

7. The adjustable wind guide hood according to claim 1, wherein the top of two inner sides of the exit plate part is at least provided with a first elastic bracket and a second elastic bracket which are used to form the plurality of snap bumps.

8. The adjustable wind guide hood according to claim 7, wherein the first elastic bracket and the second elastic bracket are provided with a first side slot and a second side slot on three surrounding sides thereof respectively, an edge of a separating end of the first elastic bracket is provided with a first snap bump, and an edge of a separating end of the second elastic bracket is provided with a second snap bump.

9. The adjustable wind guide hood according to claim 1, wherein the wind deflector comprises a thinner front deflection plate installed to the front thereof, mounted with a wind deflector protection part which is made of a silicone material.

10. The adjustable wind guide hood according to claim 1, wherein the hood housing is made of a plastic material.

11. The adjustable wind guide hood according to claim 2, wherein the fan cover is mounted on the fan device.

12. The adjustable wind guide hood according to claim 1, wherein the wind deflector comprises three positioning states, a horizontal position, a 30-degree downward rotational position and a 45-degree downward rotational position, provided for the selection of use.

13. The adjustable wind guide hood according to claim 1, wherein the wind guide hood device is separately and invertedly installed on two sides of a cooling device, the two wind deflectors are configured to be opposite to the cooling device.
